(19) United States
(12) Patent Application Publication
(10) Pub. No.: US 2009/0191473 A1
(43) Pub. Date: Jul. 30, 2009

(54) PHOTOMASK MANUFACTURING METHOD, PHOTOMASK MANUFACTURING SYSTEM, AND DEVICE MANUFACTURING METHOD

(76) Inventor: Kunihiro UGAJIN, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/357,956

(22) Filed: Jan. 22, 2009

(30) Foreign Application Priority Data
Jan. 22, 2008 (JP) 2008-011893

(51) Int. Cl. G03F 1/00; G03C 5/00; B05C 11/00

(52) U.S. Cl. 430/5; 430/30; 118/665

(57) ABSTRACT

A drawing apparatus is first adjusted so that a pattern is drawn on the photomask at a pattern position at which a position variation amount of the pattern position on a surface of the photomask due to distortion of the photomask that occurs when the photomask is held on a mask stage of an exposing apparatus is eliminated. Then, a position measuring device that measures the pattern position is adjusted so that the position variation amount is added to a result of measurement of the pattern position by the position measuring device. Finally, the pattern is drawn on the photomask by using the adjusted drawing apparatus and the pattern position of the pattern is measured by using the adjusted position measuring device.

### CROSS-REFERENCE TO RELATED APPLICATIONS

This application is based upon and claims the benefit of priority from the prior Japanese Patent Application No. 2008-011893, filed on Jan. 22, 2008; the entire contents of which are incorporated herein by reference.

### BACKGROUND OF THE INVENTION

1. Field of the Invention

The present invention relates to a photomask manufacturing method, a photomask manufacturing system, and a device manufacturing method.

2. Description of the Related Art

In a process for manufacturing a semiconductor device, a method has been employed, in which a photomask (mask for exposure) on which a predetermined pattern such as a circuit pattern is formed is held on a mask stage of an exposing apparatus, and the pattern of the photomask is transferred in a reduced size onto a wafer thereby forming a circuit pattern or the like on the wafer.

In the state that the photomask is placed on the mask stage, processes such as a pattern drawing on the photomask, a position measurement of the drawn pattern, and an exposure process to the wafer are performed. For example, in a photomask manufacturing process, a position measuring device, i.e., a device that measures a position of a pattern, measures a position of a pattern, i.e., pattern position, on the photomask in a state where no binding force is applied to the photomask. At this time, the position measuring device eliminates a measurement error due to a manufacturing error or the like of itself by correcting a measurement parameter H used for measuring a position, and measures a position in an ideal coordinate system with the measurement error eliminated. Then, accuracy in position, i.e., positional accuracy, of the pattern drawn on the photomask is evaluated based on the result of measurement obtained at the position measuring device in the ideal coordinate system. A drawing apparatus, i.e., a device that draws a pattern on a photomask, draws a pattern on the photomask by using a drawing-position adjusted parameter (adjustment parameter following the ideal coordinate system) that is generated by the position measuring device in a state where the photomask is placed on the mask stage without applying any binding force thereto.

However, when the wafer is exposed by using the photomask manufactured in the above manner, the photomask is firmly held on the mask stage by applying a binding force with a vacuum chuck or the like. The photomask is distorted due to the binding force and the positional accuracy of the pattern after transferred onto the wafer is lowered. There is need to prevent such lowering of the positional accuracy of the pattern on the wafer.

JP-A 2006-39223 (KOKAI) discloses a conventional method to address the above problem. In this method, a position variation of a pattern on a photomask that occurs when an exposing apparatus holds the photomask on a mask stage is estimated in advance. The pattern is drawn on the photomask while correcting a pattern position so that the estimated position variation is eliminated.

In the conventional method, however, when manufacturing the photomask, the position variation that occurs in the exposure is corrected by correcting only the drawing position. Therefore, when the positional accuracy of the photomask is evaluated by using a position measuring device that employs an ideal coordinate system as a reference, the pattern may be determined as defective. If the standard for ensuring the positional accuracy of the photomask to prevent the above case is relaxed, the position variation of the pattern due to factors other than the holding of the photomask in the exposure may be overlooked. Thus, high positional accuracy cannot be ensured, leading to difficulty in manufacturing a photomask ensuring high positional accuracy.

### BRIEF SUMMARY OF THE INVENTION

According to an aspect of the present invention, there is provided a method of manufacturing a photomask that includes drawing adjusting including adjusting a drawing apparatus so that a pattern is drawn on the photomask at a pattern position at which a position variation amount of the pattern position on a surface of the photomask due to distortion of the photomask that occurs when the photomask is held on a mask stage of an exposing apparatus is eliminated; position adjusting including adjusting a position measuring device that measures the pattern position so that the position variation amount is added to a result of measurement of the pattern position by using the position measuring device; drawing the pattern on the photomask by using the drawing apparatus that is adjusted at the drawing adjusting; measuring the pattern position of the pattern by using the position measuring device that is adjusted at the position adjusting; calculating a displacement amount of the pattern from a reference position based on the pattern position measured at the measuring; and determining position accuracy of the pattern based on the displacement amount calculated at the calculating.

According to another aspect of the present invention, there is provided a system for manufacturing a photomask that includes a drawing apparatus that draws a pattern on the photomask, and includes an adjusting unit that adjusts the drawing apparatus so that the pattern is drawn on the photomask at a pattern position at which a position variation amount of the pattern position on a surface of the photomask due to distortion of the photomask that occurs when the photomask is held on a mask stage of an exposing apparatus is eliminated based on the position variation amount; and a position measuring device that measures the pattern position of the pattern, the position measuring device including a position measuring unit that adjusts the position measuring device so that the position variation amount is added to a result of measurement of the pattern position, measures the pattern position of the pattern drawn on the photomask by using the drawing apparatus adjusted by the adjusting unit, and outputs the result of measurement; and a displacement-amount calculating unit that calculates a displacement amount of the pattern drawn on the photomask from a reference pattern position based on the result of the measurement.

According to still another aspect of the present invention, there is provided a method of manufacturing a device that includes drawing adjusting including adjusting a drawing apparatus so that a pattern is drawn on a photomask at a pattern position at which a position variation amount of the pattern position on a surface of the photomask due to distortion of the photomask that occurs when the photomask is held on a mask stage of an exposing apparatus is eliminated; position adjusting including adjusting a position measuring device that measures the pattern position so that the position variation amount is added to a result of measurement of the pattern position by using the position measuring device; drawing the pattern on the photomask by using the drawing apparatus that is adjusted at the drawing adjusting; measuring the pattern position of the pattern by using the position measuring device that is adjusted at the position adjusting; calculating a displacement amount of the pattern from a reference position based on the pattern position measured at the measuring; determining position accuracy of the pattern based on the displacement amount calculated at the calculating; and manufacturing a semiconductor device by using the photomask that is determined as non-defective at the determining.

### BRIEF DESCRIPTION OF THE DRAWINGS

FIG. 1 is a schematic diagram for explaining a concept of a photomask manufacturing method according to a first embodiment of the present invention;

FIG. 2 is a schematic diagram of a photomask manufacturing system shown in FIG. 1;

FIG. 3 is a block diagram of a position measuring device shown in FIG. 1;

FIG. 4 is a flowchart of a manufacturing process of the photomask according to the first embodiment of the present invention;

FIGS. 5A and 5B are graphs for explaining a method of adjusting the position measuring device;

FIG. 6 is graph for explaining a concept of a method of calculating a position adjustment parameter;

FIG. 7 is a schematic diagram for explaining a concept of a photomask manufacturing method according to a second embodiment of the present invention;

FIG. 8 is a flowchart of a manufacturing process of the photomask according to the second embodiment of the present invention; and

FIG. 9 is a block diagram of a hardware configuration of the position measuring device shown in FIG. 1.

### DETAILED DESCRIPTION OF THE INVENTION

Exemplary embodiments of a photomask manufacturing method, a photomask manufacturing system, and a device manufacturing method according to the present invention are explained in detail below with reference to the accompanying drawings. The present invention is not limited to the following embodiments.

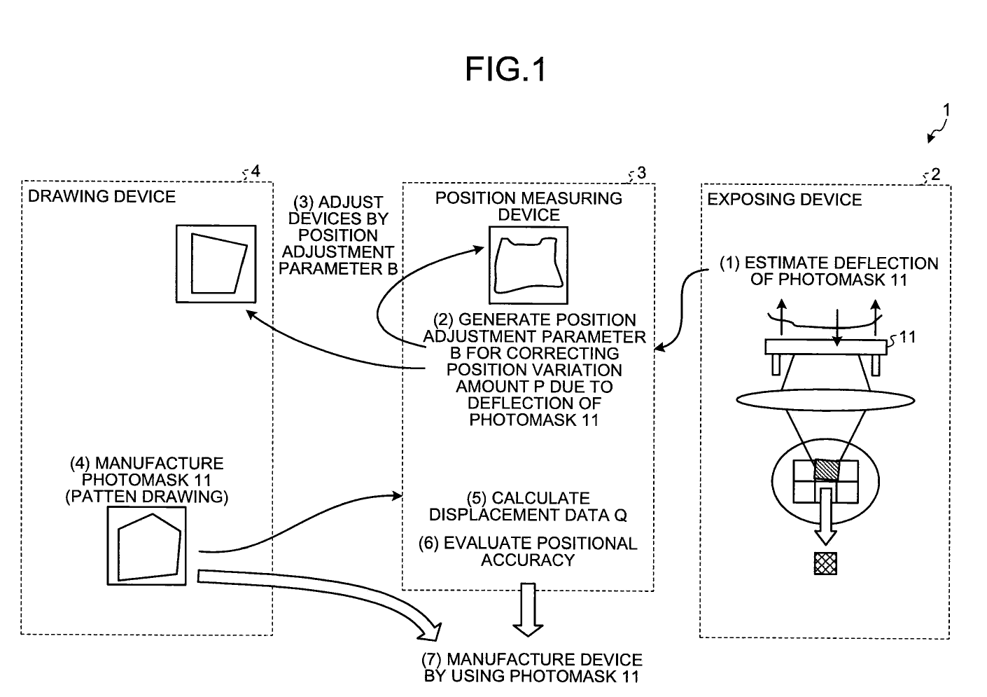

A concept of a photomask manufacturing method according to a first embodiment is explained first. FIG. 1 is a schematic diagram for explaining the concept of the photomask manufacturing method according to the first embodiment.

In a photomask manufacturing system 1, when manufacturing a photomask 11, a drawing apparatus 4 draws a pattern on a mask substrate (blanks) in such a manner that pattern distortion that occurs when an exposing apparatus 2 holds the photomask 11 is corrected. In addition, when a position measuring device 3 measures a pattern position on the photomask 11, the position measuring device 3 corrects the pattern distortion. Therefore, in the photomask manufacturing system 1, the pattern distortion on the photomask 11 is examined while taking a position variation of the pattern on the photomask 11 in the exposure into account thereby ensuring the position accuracy of the photomask 11.

Specifically, when the exposing apparatus 2 holds the photomask 11 (mask substrate) on a mask stage of the exposing apparatus 2, the exposing apparatus 2 estimates a deflection amount of the photomask 11 (process (1) in FIG. 1). Then, a position variation amount (distortion amount) (pattern-position distortion map) P of a pattern on the photomask 11 from a reference pattern position (reference design position), i.e., a position based on a design value, a theoretical value, and the like, due to the deflection amount is calculated at the position measuring device 3 or the like. The position variation amount P substantially corresponds to a displacement amount of a pattern formed on a wafer when the wafer is exposed using the photomask 11. The exposing apparatus 2 can be included in the photomask manufacturing system 1 or can be provided separately from the photomask manufacturing system 1.

Then, the position measuring device 3 generates (calculates) a position adjustment parameter B for the photomask 11 for correcting the calculated position variation amount P (process (2)). Then, the drawing apparatus 4 is adjusted in accordance with the position adjustment parameter B. In addition, the position measuring device 3 is adjusted in accordance with the position adjustment parameter B (process (3)). The drawing apparatus 4 is adjusted by correcting a drawing parameter G (not shown) that is used when drawing a pattern on the photomask 11, and the position measuring device 3 is adjusted by correcting a measurement parameter H (not shown) that is used when measuring a position of a pattern on the photomask 11.

Thereafter, the drawing apparatus 4 draws a pattern on the mask substrate thereby manufacturing the photomask 11 (process (4)). Then, the position measuring device 3 measures a pattern position on this photomask 11 and calculates displacement data Q of the pattern such as a position deviation and a displacement amount (process (5)). The displacement data Q is data indicating a displacement amount from the reference pattern position or target position data to be described below. Moreover, the position measuring device 3 determines positional accuracy of the pattern drawn on the photomask 11 and evaluates the pattern position based on the displacement data Q (process (6)). When the position measuring device 3 determines that the positional accuracy of the pattern is non-defective, a predetermined device such as a semiconductor device (e.g., complementary metal oxide semiconductor (CMOS)) is manufactured by using the photomask 11 (process (7)). The process (3) can be performed at any timing before the process (5).

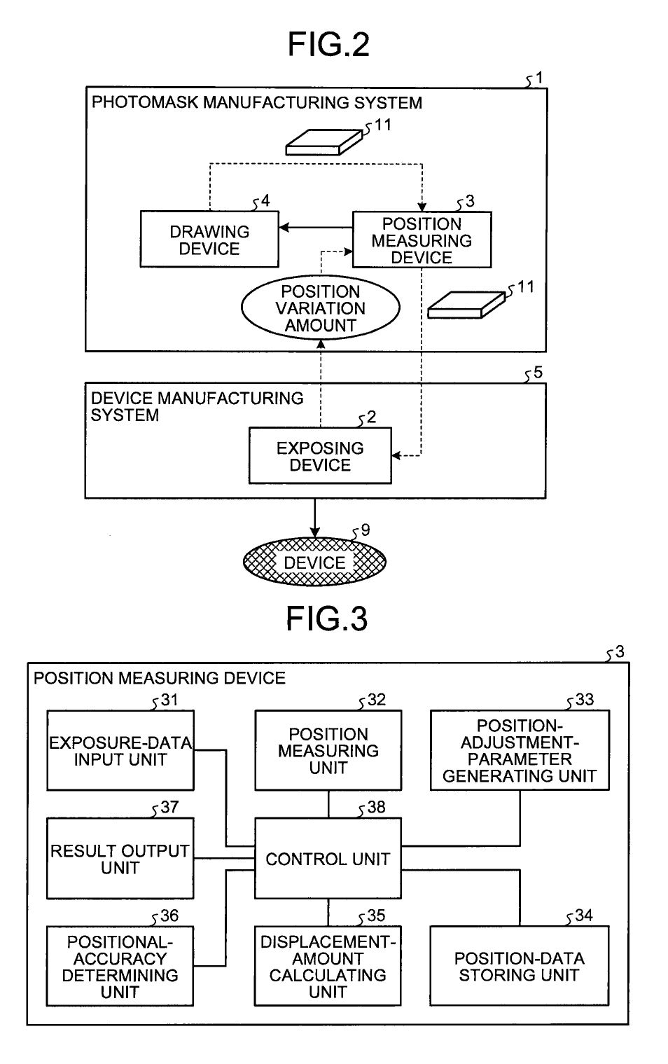

A configuration of the photomask manufacturing system 1 according to the first embodiment is explained below. FIG. 2 is a schematic diagram of the photomask manufacturing system 1 according to the first embodiment. The photomask manufacturing system 1 includes the position measuring device 3 and the drawing apparatus 4.

The exposing apparatus 2 of a device manufacturing system 5 performs an exposure process on a wafer by using the photomask 11 and includes a mask stage (not shown) that holds the photomask 11. The exposing apparatus 2 holds the photomask 11 on the mask stage by a binding force generated with a vacuum chuck or the like. The exposing apparatus 2 estimates a deflection amount of the photomask 11 that occurs when the exposing apparatus 2 holds the photomask 11 on the mask stage. Estimation of the deflection amount can be performed based on a type of the exposing apparatus 2 or information on the mask substrate, or can be performed by actually measuring a deflection amount of the photomask 11 in the state where the photomask 11 is held by the exposing apparatus 2.

The position measuring device 3 measures the pattern position on the photomask 11, and calculates the position variation amount P of the pattern due to deflection of the photomask 11, i.e., due to holding of the photomask 11 by the exposing apparatus 2. The position measuring device 3 calculates the position variation amount P from the deflection amount of the photomask 11 estimated by the exposing apparatus 2. Alternatively, it is possible that, after a pattern is actually formed on a wafer by performing the exposure process on the wafer using the photomask 11, the position measuring device 3 calculates the position variation amount P by using the wafer after development or etching. The position measuring device 3 generates the position adjustment parameter B so as to correct a measurement position to eliminate (counterbalance) the calculated position variation amount P. Before measuring the pattern position on the photomask 11, the position measuring device 3 corrects in advance the measurement parameter H used when measuring a position in accordance with the position adjustment parameter B. In other words, the position measuring device 3 adjusts itself so that the position variation amount P is added to the result of measurement of the pattern position.

Moreover, the position measuring device 3 measures the position of the pattern formed on a surface of the photomask 11 manufactured by the drawing apparatus 4, and calculates the displacement data Q of the pattern drawn on the photomask 11. The position measuring device 3 then evaluates the positional accuracy of the pattern drawn on the photomask 11, i.e., determines the quality of the pattern, based on the calculated displacement data Q.

The drawing apparatus 4 is a device, such as an electron-beam drawing apparatus, that manufactures the photomask 11 by drawing a pattern on a mask substrate. The drawing apparatus 4 is adjusted in advance, i.e., before manufacturing the photomask 11, in accordance with the position adjustment parameter B generated by the position measuring device 3. The drawing apparatus 4 includes an adjusting unit (not shown) that adjusts the drawing apparatus 4 in accordance with the position adjustment parameter B. In other words, the drawing apparatus 4 adjusts itself so that the drawing apparatus 4 draws a pattern to a pattern position at which the position variation amount P is eliminated.

The device manufacturing system 5 manufactures a device 9 by using the photomask 11 manufactured by the drawing apparatus 4. The device manufacturing system 5 includes, for example, a thin-film generating device (not shown), a resist coating device (not shown), the exposing apparatus 2, and an etching device (not shown).

For example, the mask substrate, which is used in the photomask manufacturing system 1, includes a 6-square-inch (152-square-millimeter) about 6-millimeter-thick quartz substrate (transparent substrate), an argon fluoride (ArF) halftone film provided on the quartz substrate, and a chromium (Cr) film provided on the ArF halftone film.

It is explained above that the position measuring device 3 calculates the position variation amount P; however, the position variation amount P can be calculated by some other information processing apparatus. A situation is explained below where some other information processing apparatus calculates the position variation amount P and inputs the calculated position variation amount P to the position measuring device 3.

A detailed configuration of the position measuring device 3 is explained. FIG. 3 is a block diagram of the position measuring device 3. The position measuring device 3 includes an exposure-data input unit 31, a position measuring unit 32, a position-adjustment-parameter generating unit 33, a position-data storing unit 34, a displacement-amount calculating unit 35, a positional-accuracy determining unit 36, a result output unit 37, and a control unit 38.

An information processing apparatus inputs the position variation amount P of the pattern that occurs when the photomask 11 is held by the exposing apparatus 2 to the exposure-data input unit 31. The position-adjustment-parameter generating unit 33 generates the position adjustment parameter B for correcting the position variation of the pattern based on the position variation amount P of the pattern input to the exposure-data input unit 31.

The position-data storing unit 34 stores therein target position data for the pattern position on the photomask 11 (theoretical value defined by the drawing data), the position adjustment parameter B generated in the position-adjustment-parameter generating unit 33, the reference design position that is used when calculating the displacement data Q or the like, a threshold as a reference for determining displacement, a position adjustment parameter A to be described below, and the like.

The position measuring unit 32 measures the pattern position on the photomask 11 by using the position adjustment parameters A and B stored in the position-data storing unit 34. The position adjustment parameter B is a parameter for correcting the measurement parameter H so that the result of measurement of the pattern position can be obtained in a state where the pattern distortion that occurs when the exposing apparatus 2 holds the photomask 11 is corrected. The position measuring unit 32 converts the measured pattern position into a new pattern position in which the position variation amount P is added to the measured pattern position and outputs the new pattern position to the position-data storing unit 34 or the like.

The displacement-amount calculating unit 35 calculates the displacement data Q of the pattern drawn on the photomask 11 based on the target position data stored in the position-data storing unit 34 and the pattern position (actually measured value) measured by the position measuring unit 32.

The positional-accuracy determining unit 36 evaluates the positional accuracy of the pattern drawn on the photomask 11, i.e., determines the quality of the pattern, based on the displacement data Q calculated by the displacement-amount calculating unit 35 and the threshold for determining displacement stored in the position-data storing unit 34. The result output unit 37 outputs the result of evaluation (result of determination) obtained in the positional-accuracy determining unit 36 to the outside.

The control unit 38 controls the exposure-data input unit 31, the position measuring unit 32, the position-adjustment-parameter generating unit 33, the position-data storing unit 34, the displacement-amount calculating unit 35, the positional-accuracy determining unit 36, and the result output unit 37.

The position measuring device 3 includes a mask stage (not shown). A configuration of the mask stage is explained below. The mask substrate is considerably thicker than a wafer, so that a manufacturing error of the mask substrate is also larger. The photomask 11 has deformation properties that are unique to individual mask substrates due to the manufacturing error. If binding force is applied to the photomask 11 by using a vacuum chuck or the like, the pattern on the photomask 11 gets distorted in a unique manner in accordance with the deformation properties of the photomask 11. In other words, flatness of the photomask 11 is three-dimensionally changed between before deformation of the photomask 11 (before chucking) and after deformation of the photomask 11 (after chucking), which results in displacement of the pattern on the photomask 11. Therefore, in the present embodiment, the mask stage of the position measuring device 3 has a structure (free-end holding structure) with which the stage holds the photomask 11 or a photomask 51 for adjustment (hereinafter, “adjustment mask 51”) to be described below without applying any binding force thereto. With this structure, the position measuring device 3 can measure the pattern position without being affected by the deformation that is unique to each photomask 11.

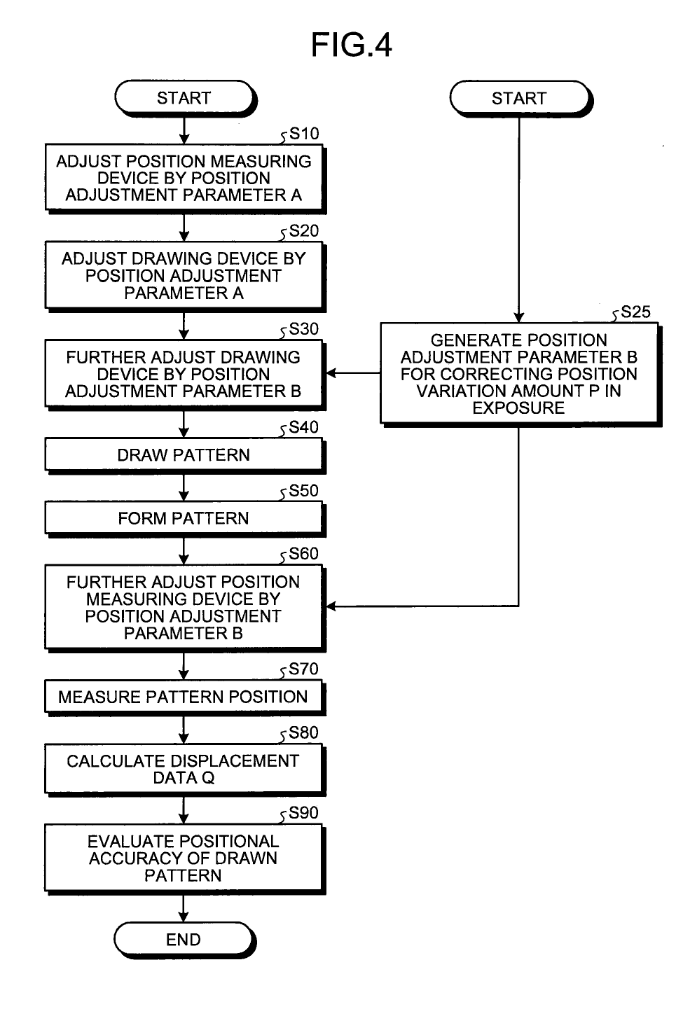

A method of manufacturing the photomask 11 according to the first embodiment is explained below. FIG. 4 is a flowchart of a manufacturing process of the photomask 11 according to the first embodiment. First, at Step S10, the position measuring device 3 corrects distortion (measuring error uniquely to the device) of a pattern due to a manufacturing error or the like of the position measuring device 3 itself.

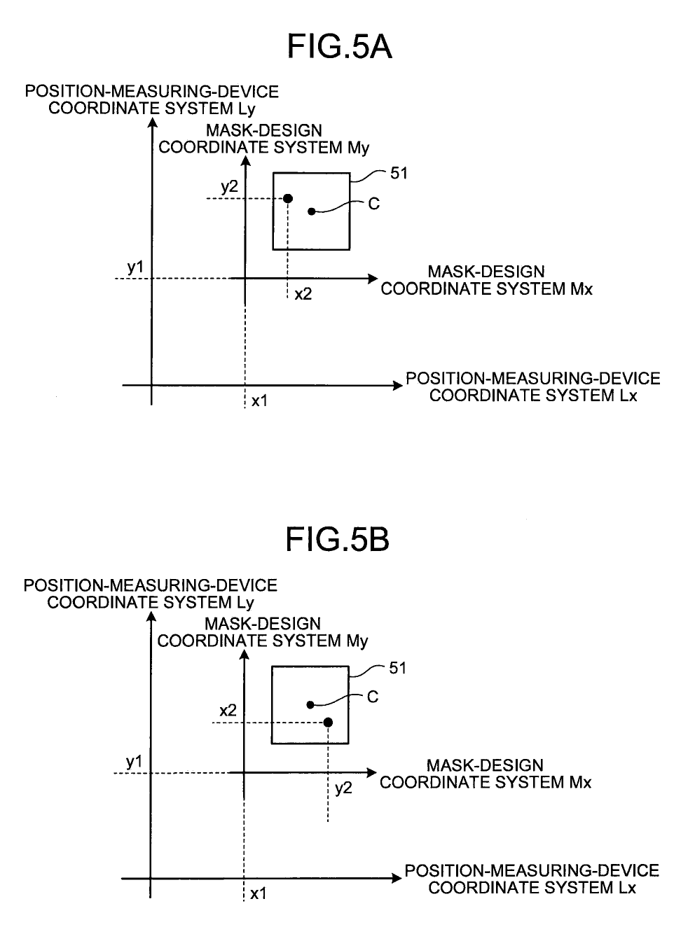

Specifically, the position measuring device 3 adjusts itself by using the position adjustment parameter A for correcting distortion of the pattern due to a manufacturing error or the like of the position measuring device 3 itself. FIGS. 5A and 5B are graphs for explaining a method of adjusting the position measuring device 3. In FIG. 5A, a measurement point on the photomask 11 is illustrated in a case where the photomask 11 is placed on the mask stage without the photomask 11 being rotated in the plane of the photomask 11. In FIG. 5B, the measurement point on the photomask 11 is illustrated in a case where the photomask 11 is placed on the mask stage after the photomask 11 is rotated 180 degrees in the plane of the photomask 11.

As shown in FIG. 5A, the adjustment mask 51 is placed on the mask stage of the position measuring device 3 (zero-degree direction). The adjustment mask 51 is a photomask on which a position evaluation pattern (not shown) is formed at a plurality of positions (e.g., at four corners) on the surface of the photomask. The position measuring device 3 measures positions of the position evaluation patterns in a certain order.

Upon measuring a position of a predetermined measurement point (first point) on the adjustment mask 51, the result of measurement (X, Y) can be expressed by Equation (1) in which a coordinate system of the position measuring device 3 (position-measuring-device coordinate system Lx, Ly) and a design coordinate system (mask-design coordinate system Mx, My) of the photomask 11 as an ideal coordinate system are summed. In Equation (1), (X, Y) are coordinates with the origin in the position-measuring-device coordinate system Lx, Ly as a reference, (x1, y1) are coordinates in the position-measuring-device coordinate system Lx, Ly, and (x2, y2) are coordinates in the mask-design coordinate system Mx, My.

X=(x1−Lx)+(x2−Mx)=ax·Lx

Y=(y1−Ly)+(y2−My)=ay·Ly (1)

As shown in FIG. 5B, the position measuring unit 32 changes a direction in which the adjustment mask 51 is held (hereinafter, “holding direction”) by 180 degrees around a center point C of the adjustment mask 51 in the surface that is parallel to the main surface of the adjustment mask 51, and measures the position of the position evaluation pattern. When the holding direction of the adjustment mask 51 is rotated 180 degrees, the measurement point (x2, y2) is changed to (y2, x2). Therefore, the result of measurement obtained at the position measuring unit 32 can be expressed by Equation (2) in the similar manner to Equation (1):

X=(x1·Lx)+(y2·Mx)=bx·Lx

Y=(y1·Ly)+(x2·My)=by·Ly (2)

Comparing Equations (1) and (2), the difference (bx−ax) is a value corresponding to (y2−x2) in the mask-design coordinate system Mx, My. However, the position measuring device 3 itself has a manufacturing error and the like, so that a predetermined difference (measurement error) occurs in the actual measurement value.

Similarly, the position measuring unit 32 changes the holding direction of the adjustment mask 51 by 90 degrees and 270 degrees in the plane that is parallel to the main surface of the adjustment mask 51, and measures the positions of the position evaluation pattern. By comparing the result of measurements with the result in the case of the zero-degree direction, a predetermined difference occurs in each holding direction.

Upon the position measuring unit 32 measures measurement points (second point to n-th point (n is a positive integer)) on the adjustment mask 51, a predetermined difference occurs in four directions at an angle of 0 degree, 90 degrees, 180 degrees, and 270 degrees at each measurement point.

In this manner, by measuring each pattern position at a plurality of points on the adjustment mask 51, the position measuring unit 32 obtains differential data (distribution in the surface on the adjustment mask 51) with respect to the mask-design coordinate system.

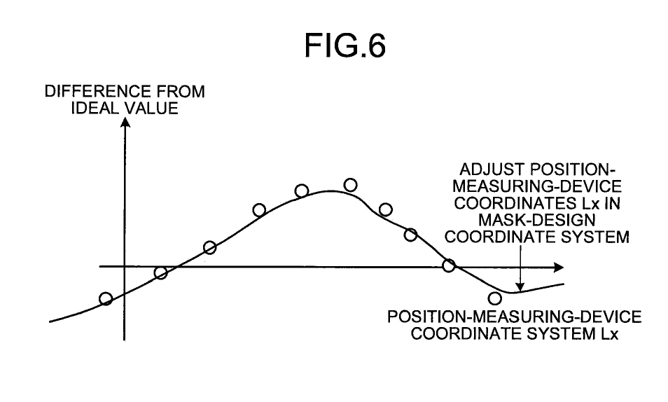

FIG. 6 is graph for explaining a concept of a method of calculating the position adjustment parameter A. In the position-adjustment-parameter generating unit 33, the differential data is subjected to polynomial approximation and the position adjustment parameter A is generated (calculated) so that variation of the result of measurements in each holding direction is minimal. Specifically, the position adjustment parameter (first adjustment parameter) A is generated so that the same position measurement result can be obtained in each of the four directions when the photomask 11 is held in the four directions. Concretely, the position-adjustment-parameter generating unit 33 converts the position-measuring-device coordinate system of the position measuring device 3 so that the difference that occurs between data on positions that is to be measured when the photomask 11 is rotated if there is no manufacturing error in the position measuring device 3 and the data on positions actually measured by the position measuring unit 32 is minimal. The position-adjustment-parameter generating unit 33 stores the generated position adjustment parameter A in the position-data storing unit 34.

In the position-adjustment-parameter generating unit 33, the measurement coordinate system to which the generated position adjustment parameter A is employed is defined as a new ideal coordinate system. In other words, in the position-adjustment-parameter generating unit 33, the measurement parameter H for measuring a position is adjusted in accordance with the position adjustment parameter A, whereby the position measuring device 3 can perform correction including correction of difference in orientation of the photomask 11 when the photomask 11 is placed on the mask stage. For example, the difference in orientation of the photomask 11 includes displacement of the pattern position due to placement of the photomask 11 in an inclined state or in a rotated state with respect to the plane of the photomask 11. Therefore, in the position measuring device 3, it is possible to eliminate a position error such as an orthogonal-degree component error, an X-direction component error, and a Y-direction component error of the position measured value due to a manufacturing error or the like of the position measuring device 3, and measure the position independent of the way of holding the photomask 11 (displacement of the pattern position due to the holding).

Next, at Step S20, the drawing apparatus 4 adjusts itself by using the position adjustment parameter A to follow the ideal coordinate system defined in the position measuring device 3. Incidentally, when the position adjustment parameter A cannot be directly used for adjusting the drawing apparatus 4, the position adjustment parameter A is converted into some other parameter corresponding to the drawing apparatus 4 and the drawing apparatus 4 adjusts itself by using this parameter.

At Step S25, the position measuring device 3 estimates the position variation amount P (e.g., position deviation in pattern after transfer) of the pattern due to deflection of the photomask 11 when the photomask 11 is held by the exposing apparatus 2. Alternatively, the exposing apparatus 2, or a device other than the position measuring device 3, can estimate the position variation amount P. The position-adjustment-parameter generating unit 33 then generates the position adjustment parameter B (second adjustment parameter) to eliminate the estimated position variation amount P. The position adjustment parameter B is a parameter for correcting the position variation amount P that occurs in the exposure. The position-adjustment-parameter generating unit 33 stores the generated position adjustment parameter B in the position-data storing unit 34.

At Step S30, the drawing apparatus 4 further adjusts itself by further correcting the drawing parameter G that is corrected by the position adjustment parameter A by the position adjustment parameter B. In other words, the drawing apparatus 4 corrects the drawing parameter G by a parameter obtained by combining the position adjustment parameters A and B.

Then, at Step S40, a desired pattern is drawn on the mask substrate (mask substrate that is used when generating the position adjustment parameter B) by using the further-adjusted drawing apparatus 4, and the pattern is formed on the mask substrate by performing pattern forming processing such as development and etching on the mask substrate at Step S50. Specifically, the mask substrate on which a pattern is drawn by the drawing apparatus 4 is subjected to a post exposure bake (PEB) and a development process to form a resist pattern. Then, the Cr film and the halftone film are etched by the etching device with the resist pattern as a mask, thereby manufacturing the photomask 11.

At Step S60, in the position measuring device 3 that is adjusted to follow the ideal coordinate system, the position-adjustment-parameter generating unit 33 further corrects the measurement parameter H in accordance with the position adjustment parameter B that is used for further adjusting the drawing apparatus 4. In other words, the position-adjustment-parameter generating unit 33 corrects the measurement parameter H in accordance with a parameter obtained by combining the position adjustment parameters A and B.

At Step S70, the position measuring device 3 that is further adjusted in accordance with the position adjustment parameters A and B causes the position measuring unit 32 to measure the pattern position of the manufactured photomask 11. The result of measurement of the pattern position in the position measuring device 3 is the result after the position measuring device 3 is adjusted in accordance with the position adjustment parameter B, so that the result of measurement obtained by the position measuring device 3 corresponds to a value that is obtained by correcting the pattern position on the photomask 11 in accordance with the position variation amount P.

At Step S80, the displacement-amount calculating unit 35 calculates the displacement data Q of the pattern drawn on the photomask 11 based on the pattern position measured by the position measuring unit 32 and the target position data defined by the drawing data.

At Step S90, the positional-accuracy determining unit 36 evaluates the positional accuracy of the pattern drawn on the photomask 11 based on the calculated displacement data Q and the threshold for determining displacement stored in the position-data storing unit 34. The result output unit 37 outputs the result of evaluation performed by the positional-accuracy determining unit 36. The device manufacturing system 5, when the pattern drawn on the photomask 11 is evaluated as non-defective, manufactures a predetermined device, such as a semiconductor device, by using the manufactured photomask 11.

Specifically, first, resist is coated on a wafer to be used for manufacturing a device. Then, the manufactured photomask 11 and the wafer are set on the exposing apparatus 2, and the resist coated on the wafer is exposed through the photomask 11. Thereafter, typical resist process such as development process is performed on the wafer thereby forming a resist pattern on the wafer.

Next, the wafer is etched with the resist pattern as a mask, so that a device pattern is formed on the wafer. Then, by repeating film generation, exposure, development, etching, and the like, a pattern such as an element isolation trench, a transistor, wiring, an electrode, a contact hole, and the like is formed on a wafer in order. At this time, when forming each device pattern by the exposure, the photomask 11 corresponding to a device pattern is used. Therefore, when manufacturing a device, various kinds of photomasks 11 are used. Thus, a device pattern (multilayer pattern) formed by laminating a plurality of layers is formed on the wafer.

In the present embodiment, the position measuring device 3 generates the position adjustment parameters A and B; however, a predetermined information processing apparatus such as a personal computer (PC) can generate the position adjustment parameters A and B. Moreover, a predetermined information processing apparatus can calculate the displacement data Q of the pattern drawn on the photomask 11 based on the pattern position measured by the position measuring device 3 and the target position data defined in the drawing data. Furthermore, a predetermined information processing apparatus can evaluate the positional accuracy of the pattern drawn on the photomask 11 based on the displacement data Q.

Moreover, in the present embodiment, the exposing apparatus 2 estimates a deflection amount of the photomask 11 when the photomask 11 is held on the mask stage of the exposing apparatus 2; however, a predetermined information processing apparatus other than the exposing apparatus 2 can estimate a deflection amount of the photomask 11.

Furthermore, in the present embodiment, every time one mask substrate is manufactured, the position measuring device 3 and the drawing apparatus 4 are adjusted to the ideal coordinate system; however, the position measuring device 3 and the drawing apparatus 4 can be adjusted to the ideal coordinate system at any timing. For example, the position measuring device 3 and the drawing apparatus 4 can be adjusted every predetermined number of photomask manufacturing or once a day according to the stability of the devices.

Moreover, in the present embodiment, for measuring the position of the position evaluation pattern on the adjustment mask 51, the holding direction of the adjustment mask 51 is rotated in four directions at an angle of 0 degree, 90 degrees, 180 degrees, and 270 degrees; however, the holding direction of the adjustment mask 51 can be rotated in three directions or less, or five directions or more. For example, the holding direction of the adjustment mask 51 can be rotated in two directions at an angle of 0 degree and 90 degrees according to the adjustment accuracy or the like. Moreover, a plurality of the adjustment masks 51 can be used for generating the position adjustment parameter A to improve the adjustment accuracy.

Furthermore, in the present embodiment, the position measuring device 3 and the drawing apparatus 4 are adjusted in advance in accordance with the position adjustment parameter A for correcting a manufacturing error thereof; however, this process can be omitted.

In this manner, according to the first embodiment, both the position measuring device 3 and the drawing apparatus 4 are further adjusted in accordance with the position adjustment parameter B for correcting the position variation amount P that occurs in the exposure.

Therefore, according to the first embodiment, even when the pattern position varies due to factors (e.g., thermal expansion of the photomask 11) other than deflection of the photomask 11 that occurs when the exposing apparatus 2 holds the photomask 11, the position measuring device 3 can accurately measure position variation from the proper pattern position. Accordingly, because the pattern position on the photomask 11 can be measured accurately, the positional accuracy of the photomask 11 can be evaluated accurately. Therefore, by exposing a wafer by using the photomask 11, a pattern can be formed on the wafer at the correct position, i.e., with high positional accuracy, so that a device with less distortion can be formed on the wafer.

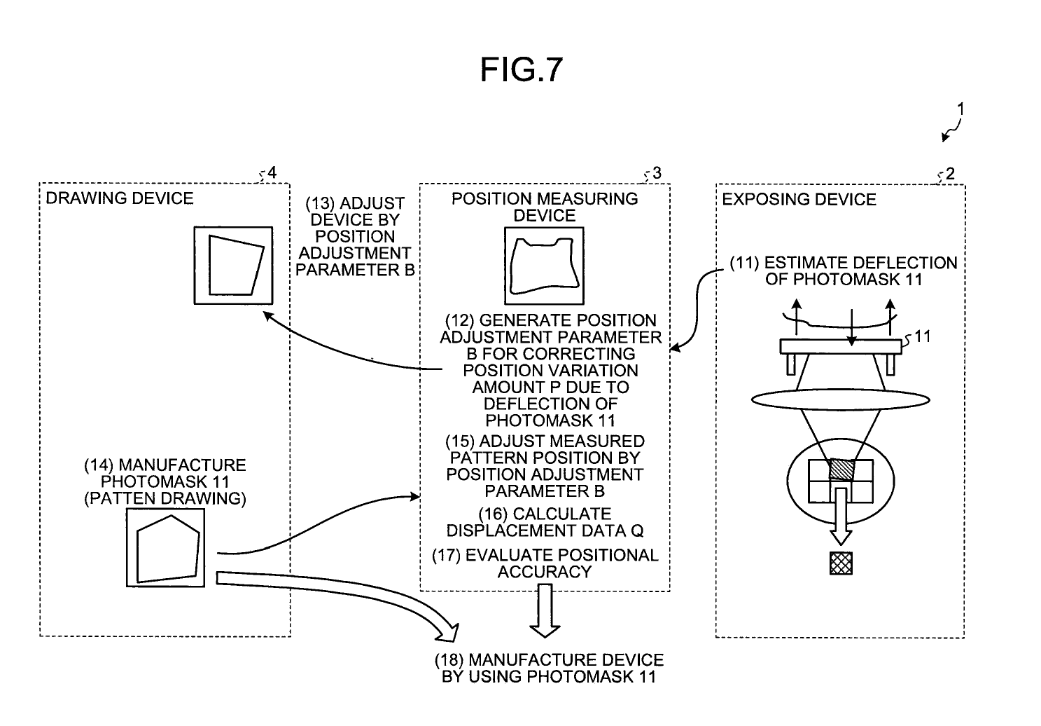

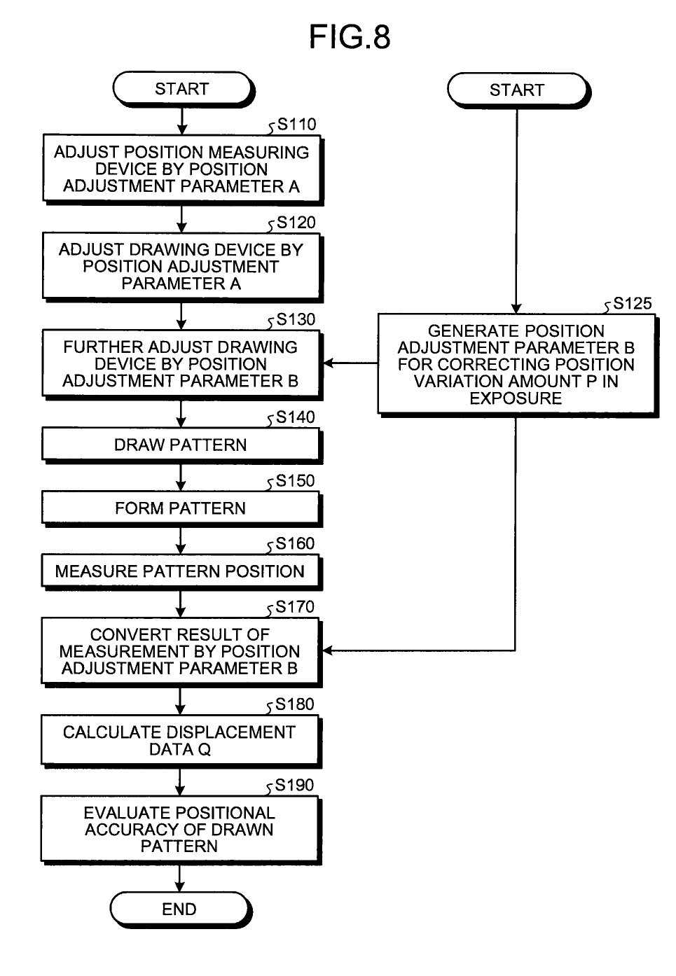

Next, a method of manufacturing a photomask according to a second embodiment of the present invention is explained with reference to FIGS. 7 and 8. In the second embodiment, after measuring the pattern position of the manufactured photomask 11 by the position measuring device 3, the positional accuracy of the pattern position is evaluated by converting the pattern position after the measurement into a position corresponding to the position adjustment parameter B.

A concept of a photomask manufacturing method according to the second embodiment is explained. FIG. 7 is a schematic diagram for explaining the concept of the photomask manufacturing method according to the second embodiment. In FIG. 7, components that are the same as those in FIG. 1 in the first embodiment are given the same reference numerals, and explanation thereof is omitted.

When the exposing apparatus 2 holds the photomask 11 on the mask stage of the exposing apparatus 2, the exposing apparatus 2 estimates a deflection amount of the photomask 11 (process (11)). The position measuring device 3 calculates the position variation amount P of the pattern of the photomask 11 due to the deflection and then calculates (generates) the position adjustment parameter B for correcting the position variation amount P (process (12)). Then, the drawing apparatus 4 is adjusted in accordance with the calculated position adjustment parameter B (process (13)).

Thereafter, the drawing apparatus 4 manufactures the photomask 11 by drawing a pattern on the mask substrate (process (14)). Then, the position measuring device 3 measures a position of the pattern on the photomask 11 manufactured by the drawing apparatus 4. Moreover, the position measuring device 3 corrects the measured pattern position in accordance with the position adjustment parameter B. In other words, the position measuring device 3 converts the measured pattern position into a coordinate system for the position adjustment parameter B (process (15)). In the similar manner to the first embodiment, because the position measuring device 3 is adjusted in advance in accordance with the position adjustment parameter A, the pattern position on the photomask 11 (result of measurement) is corrected in accordance with the position adjustment parameters A and B.

Thereafter, the position measuring device 3 calculates the displacement data Q of the pattern drawn on the photomask 11 (process (16)). Moreover, the position measuring device 3 determines the positional accuracy of the pattern drawn on the photomask 11 and evaluates the pattern position based on the displacement data Q (process (17)). When the position measuring device 3 determines that the positional accuracy of the pattern is non-defective, a predetermined semiconductor device is manufactured by using the photomask 11 (process (18)).

A method of manufacturing the photomask 11 according to the second embodiment is explained. FIG. 8 is a flowchart of a manufacturing process of the photomask 11 according to the second embodiment. The procedures same as those in FIG. 4 in the first embodiment are not explained here. In manufacturing the photomask 11 according to the second embodiment, procedures at Steps S110 to S150 in FIG. 8 are the same as those at Steps S10 to S50 in FIG. 4 in the first embodiment.

At Step S110, the position measuring device 3 calculates the position adjustment parameter A by using the adjustment mask 51 to correct distortion of a pattern due to a manufacturing error or the like of the position measuring device 3 itself. Then, the position measuring device 3 adjusts itself by using the position adjustment parameter A. In the position measuring device 3, the measurement coordinate system employing the calculated position adjustment parameter A is defined as a new ideal coordinate system.

Next, at Step S120, the drawing apparatus 4 adjusts itself by using the position adjustment parameter A to follow the ideal coordinate system defined in the position measuring device 3. At Step S125, the exposing apparatus 2 estimates the position variation amount P of the pattern due to deflection of the photomask 11 when being held by the exposing apparatus 2, and the position-adjustment-parameter generating unit 33 then generates the position adjustment parameter B to eliminate the estimated position variation amount P.

At Step S130, the drawing apparatus 4 further adjusts itself by further correcting the drawing parameter G corrected in accordance with the position adjustment parameter A by the position adjustment parameter B. Thereafter, at Step S140, a desired pattern is drawn on the mask substrate by using the further-adjusted drawing apparatus 4, and the pattern is formed on the mask substrate at Step S150. The above procedures at Steps S110 to S150 correspond to those at Steps S10 to S50 in FIG. 4 in the first embodiment.

Next, at Step S160, the position measuring device 3 causes the position measuring unit 32 to measure the pattern position of the manufactured photomask 11. Then, at Step S170, the displacement-amount calculating unit 35 converts the result of measurement of the pattern position into a measurement position corresponding to the position adjustment parameter B. Therefore, the displacement-amount calculating unit 35 converts the result of measurement (pattern position) to follow the coordinate system that is formed in accordance with the position adjustment parameter B. In other words, the displacement-amount calculating unit 35 converts the measured pattern position into a new pattern position in which the position variation amount P is added to the measured pattern position. With the above processing, the pattern of the photomask 11 is corrected in accordance with the position adjustment parameters A and B. In other words, the measurement result after being converted in accordance with the position adjustment parameter B corresponds to the value that is obtained by correcting the pattern position on the photomask 11 in accordance with the position variation amount P.

At Step S180, the displacement-amount calculating unit 35 calculates the displacement data Q of the pattern drawn on the photomask 11 based on the pattern position (result of measurement) after the conversion in accordance with the position adjustment parameter B and the target position data defined in the drawing data.

Furthermore, at Step S190, the positional-accuracy determining unit 36 evaluates the positional accuracy of the pattern drawn on the photomask 11 based on the displacement data Q calculated by the displacement-amount calculating unit 35 and the threshold for determining displacement stored in the position-data storing unit 34. Thereafter, in the similar manner to the first embodiment, the result output unit 37 outputs the result of evaluation obtained by the positional-accuracy determining unit 36 to the outside. When the pattern drawn on the photomask 11 is evaluated as non-defective, a predetermined device is manufactured by using the photomask 11.

In the present embodiment, the position measuring device 3 is adjusted by the position adjustment parameter A before the position measuring device 3 measures the pattern position on the photomask 11; however, the adjustment of the position measuring device 3 by the position adjustment parameter A can be omitted. In this case, the position measuring device 3 can convert the result of measurement by the position adjustment parameters A and B.

In this manner, in the second embodiment, after measuring the pattern position of the photomask 11, the position measuring device 3 converts the result of measurement to follow the position adjustment parameter B used for further adjustment of the drawing apparatus 4.

Therefore, according to the second embodiment, the positional accuracy of the photomask 11 can be evaluated properly similarly to the first embodiment. Thus, by exposing a wafer by using the photomask 11, a pattern can be formed on the wafer at the correct position, so that a device with less distortion can be formed on the wafer.

Next, a method of manufacturing the photomask 11 according to a third embodiment is explained. In the third embodiment, the position adjustment parameters A and B are each defined as a polynomial of coordinates defined in the ideal coordinate system (polynomial with respect to the pattern coordinates of the photomask 11).

The position adjustment parameter A used for adjusting the position measuring device 3 can be expressed as a parameter using a polynomial of the ideal coordinate system (x, y). For example, assuming that coordinates after being corrected by the position adjustment parameter A are adjusted position coordinates (X1, Y1), the coordinates (X1, Y1) is approximated by Equation (3) where (x, y) is a mask design coordinate system.

X1−x=a₀+a₁x+a₂y+a₃x²+a₄xy+a₅y²

Y1−y=b₀+b₁x+b₂y+b₃x²+b₄xy+b₅y² (3)

When the adjusted position coordinates (position-measuring-device coordinate system) match coordinates in the ideal coordinate system (mask design coordinate system), a₀=a₁=a₂=a₃=a₄=a₅= . . . =b₀=b₁=b₂=b₃=b₄=b₅= . . . =0. Next, when coordinates after being adjusted by the position adjustment parameter B for correcting deflection of the mask substrate are adjusted position coordinates (X2, Y2), the coordinates (X2, Y2) is approximated by Equation (4).

X2−x=c₀+c₁x+c₂y+c₃x²+c₄xy+c₅y

Y2−y=d₀+d₁x+d₂y+d₃x²+d₄xy+d₅y² (4)

Therefore, adjusted position coordinates (X3, Y3) after the position measuring device 3 is adjusted by a parameter obtained by combining the position adjustment parameters A and B is approximated by Equation (5).

X3−x=(a₀+c₀)+(a₁+c₁)x+(a₂+c₂)y+(a₃+c₃)x²+(a₄+c₄)xy+(a₅+c₅)y²

Y3−y=(b₀+d₀)+(b₁+d₁)x+(b₂+d₂)y+(b₃+d₃)x²+(b₄+d₄)xy+(b₅+d₅)y² (5)

In the position measuring device 3, adjustment of itself and conversion of the result of measurement are performed in accordance with the position adjustment parameters A and B calculated from the polynomials such as Equations (3) to (5).

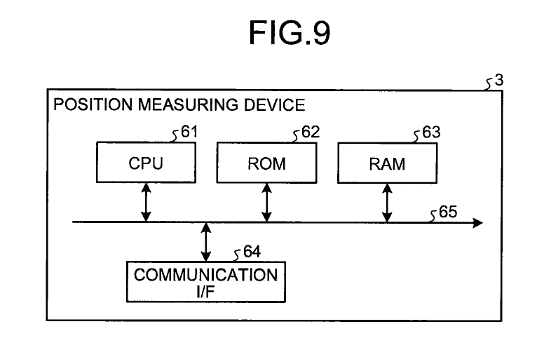

Next, a hardware configuration of the position measuring device 3 explained in the first to third embodiments is explained with reference to FIG. 9. FIG. 9 is a block diagram of the hardware configuration of the position measuring device 3. As shown in FIG. 9, the position measuring device 3 includes a read only memory (ROM) 62 that, for example, stores therein computer programs for measuring the pattern position on the photomask 11, correcting the measurement parameter H, and the like, a central processing unit (CPU) 61 that controls each unit of the position measuring device 3 in accordance with the computer programs stored in the ROM 62, a random access memory (RAM) 63 that stores therein various data necessary for controlling the position measuring device 3, a communication interface (I/F) 64 that connects the position measuring device 3 to the network for communication, and a bus 65 that connects the units in the position measuring device 3, as the hardware configuration.

A computer program for correcting the measurement parameter H can be provided in such a way that the computer program is recorded as an installable format file or executable format file in a computer-readable recording medium such as a compact disk read only memory (CD-ROM), a flexible disk (FD), a compact disk recordable (CD-R), and a digital versatile disk (DVD).

Moreover, computer programs such as the computer program for correcting the measurement parameter H can be stored in a computer connected to the network such as the Internet and provided by a user downloading the computer programs through the network, or the computer programs can be provided or distributed through the network.

According to the third embodiment, the position adjustment parameters A and B are each expressed in a polynomial, so that it is easy to calculate a parameter obtained by combining the position adjustment parameters A and B due to the additivity of a polynomial. Thus, the position measuring device 3 can easily calculate the position of the pattern drawn on the photomask 11.

The methods of manufacturing the photomask 11 according to the first to third embodiments can be combined.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of manufacturing a photomask comprising:
drawing adjusting including adjusting a drawing apparatus so that a pattern is drawn on the photomask at a pattern position at which a position variation amount of the pattern position on a surface of the photomask due to distortion of the photomask that occurs when the photomask is held on a mask stage of an exposing apparatus is eliminated;
position adjusting including adjusting a position measuring device that measures the pattern position so that the position variation amount is added to a result of measurement of the pattern position by using the position measuring device;
drawing the pattern on the photomask by using the drawing apparatus that is adjusted at the drawing adjusting;
measuring the pattern position of the pattern by using the position measuring device that is adjusted at the position adjusting;
calculating a displacement amount of the pattern from a reference position based on the pattern position measured at the measuring; and
determining position accuracy of the pattern based on the displacement amount calculated at the calculating.

2. The method according to claim 1, further comprising defining a first position adjustment parameter for correcting distortion of the pattern attributed to the position measuring device and a second position adjustment parameter for correcting the position variation amount as a polynomial of coordinates defined in an ideal coordinate system, wherein
the drawing adjusting includes adjusting the drawing apparatus in accordance with the first position adjustment parameter and the second position adjustment parameter, and
the position adjusting includes adjusting the position measuring device in accordance with the first position adjustment parameter and the second position adjustment parameter.

3. The method according to claim 1, wherein
the drawing adjusting includes adjusting the drawing apparatus by correcting a drawing parameter, which is used at the drawing, in accordance with the first position adjustment parameter and the second position adjustment parameter, and
the position adjusting includes adjusting the position measuring device by correcting a measurement parameter, which is used at the measuring, in accordance with the first position adjustment parameter and the second position adjustment parameter.

4. The method according to claim 1, further comprising:
estimating an amount of the distortion of the photomask based on at least one of a type of the exposing apparatus and information on a mask substrate of the photomask; and
calculating the position variation amount based on the amount of the distortion.

5. The method according to claim 1, further comprising:
measuring an amount of the distortion of the photomask in a state where the photomask is held on the mask stage; and
calculating the position variation amount based on the amount of the distortion.

6. The method according to claim 1, further comprising:
forming the pattern on a wafer by exposing the wafer by using the photomask that is held on the mask stage; and
calculating the position variation amount by using the pattern formed on the wafer at the forming.

7. A system for manufacturing a photomask comprising:
a drawing apparatus that draws a pattern on the photomask, and includes an adjusting unit that adjusts the drawing apparatus so that the pattern is drawn on the photomask at a pattern position at which a position variation amount of the pattern position on a surface of the photomask due to distortion of the photomask that occurs when the photomask is held on a mask stage of an exposing apparatus is eliminated based on the position variation amount; and
a position measuring device that measures the pattern position of the pattern, the position measuring device including
a position measuring unit that adjusts the position measuring device so that the position variation amount is added to a result of measurement of the pattern position, measures the pattern position of the pattern drawn on the photomask by using the drawing apparatus adjusted by the adjusting unit, and outputs the result of measurement; and
a displacement-amount calculating unit that calculates a displacement amount of the pattern drawn on the photomask from a reference pattern position based on the result of the measurement.

8. The system according to claim 7, wherein a first position adjustment parameter for correcting distortion of the pattern attributed to the position measuring device is defined and a second position adjustment parameter for correcting the position variation amount as a polynomial of coordinates defined in an ideal coordinate system is defined, wherein
the drawing apparatus is adjusted in accordance with the first position adjustment parameter and the second position adjustment parameter, and
the position measuring device is adjusted in accordance with the first position adjustment parameter and the second position adjustment parameter.

9. The system according to claim 7, wherein
the drawing apparatus is adjusted by correcting a drawing parameter, which is used by the drawing apparatus when drawing the pattern on the photomask, in accordance with the first position adjustment parameter and the second position adjustment parameter, and
the position measuring device is adjusted by correcting a measurement parameter, which is used by the position measuring device when measuring the pattern position of the pattern, in accordance with the first position adjustment parameter and the second position adjustment parameter.

10. The system according to claim 7, wherein
an amount of the distortion of the photomask is estimated based on at least one of a type of the exposing apparatus and information on a mask substrate of the photomask, and
the position variation amount is calculated based on the amount of the distortion.

11. The system according to claim 7, wherein
an amount of the distortion of the photomask is measured in a state where the photomask is held on the mask stage, and
the position variation amount is calculated based on the amount of the distortion.

12. The system according to claim 7, wherein
the pattern is formed on a wafer by exposing the wafer by using the photomask that is held on the mask stage, and
the position variation amount is calculated by using the pattern formed on the wafer.

13. A method of manufacturing a device comprising:
drawing adjusting including adjusting a drawing apparatus so that a pattern is drawn on a photomask at a pattern position at which a position variation amount of the pattern position on a surface of the photomask due to distortion of the photomask that occurs when the photomask is held on a mask stage of an exposing apparatus is eliminated;
position adjusting including adjusting a position measuring device that measures the pattern position so that the position variation amount is added to a result of measurement of the pattern position by using the position measuring device;
drawing the pattern on the photomask by using the drawing apparatus that is adjusted at the drawing adjusting;
measuring the pattern position of the pattern by using the position measuring device that is adjusted at the position adjusting;
calculating a displacement amount of the pattern from a reference position based on the pattern position measured at the measuring;
determining position accuracy of the pattern based on the displacement amount calculated at the calculating; and
manufacturing a semiconductor device by using the photomask that is determined as non-defective at the determining.

14. The method according to claim 13, further comprising defining a first position adjustment parameter for correcting distortion of the pattern attributed to the position measuring device and a second position adjustment parameter for correcting the position variation amount as a polynomial of coordinates defined in an ideal coordinate system, wherein
the drawing adjusting includes adjusting the drawing apparatus in accordance with the first position adjustment parameter and the second position adjustment parameter, and
the position adjusting includes adjusting the position measuring device in accordance with the first position adjustment parameter and the second position adjustment parameter.

15. The method according to claim 13, wherein
the drawing adjusting includes adjusting the drawing apparatus by correcting a drawing parameter, which is used at the drawing, in accordance with the first position adjustment parameter and the second position adjustment parameter, and
the position adjusting includes adjusting the position measuring device by correcting a measurement parameter, which is used at the measuring, in accordance with the first position adjustment parameter and the second position adjustment parameter.

16. The method according to claim 13, further comprising:
estimating an amount of the distortion of the photomask based on at least one of a type of the exposing apparatus and information on a mask substrate of the photomask; and
calculating the position variation amount based on the amount of the distortion.

17. The method according to claim 13, further comprising:
measuring an amount of the distortion of the photomask in a state where the photomask is held on the mask stage; and
calculating the position variation amount based on the amount of the distortion.

18. The method according to claim 13, further comprising:
forming the pattern on a wafer by exposing the wafer by using the photomask that is held on the mask stage; and
calculating the position variation amount by using the pattern formed on the wafer at the forming.
